(19) United States
(12) Patent Application Publication
(10) Pub. No.: US 2016/0163533 A1
(43) Pub. Date: Jun. 9, 2016

(54) TANTALUM OXIDE FILM REMOVAL METHOD AND APPARATUS

(71) Applicant: TOKYO ELECTRON LIMITED, Tokyo (JP)

(72) Inventors: Kazuya DOBASHI, Yamanashi (JP); Akihito HAGIWARA, Yamanashi (JP)

(73) Assignee: TOKYO ELECTRON LIMITED, Tokyo (JP)

(21) Appl. No.: 14/900,566

(22) PCT Filed: Apr. 9, 2014
(86) PCT No.: PCT/JP2014/060318

§ 371 Date: Dec. 21, 2015

(30) Foreign Application Priority Data
Jun. 21, 2013 (JP) 2013-130935

(51) Int. Cl. H01L 21/02; H01L 21/687; H01L 21/67

(52) U.S. Cl. CPC H01L 21/0206; H01L 21/0209; H01L 21/67051; H01L 21/68764

(57) ABSTRACT

In a tantalum oxide film removal method and apparatus, a silicon substrate having a tantalum oxide film is supported on a spin chuck. A mixed aqueous solution including hydrofluoric acid and organic acid is supplied to the silicon substrate while rotating the silicon substrate together with the spin chuck. The mixed aqueous solution comes into contact with the tantalum oxide film existing on the silicon substrate to remove the tantalum oxide film by the chemical reaction therebetween.

### CROSS REFERENCE

This application is a National Stage Application of, and claims priority to, PCT Application No. PCT/JP2014/060318, filed on Apr. 9, 2014, entitled “TANTALUM OXIDE FILM REMOVAL METHOD, AND REMOVAL DEVICE,” which claims priority to Japanese Patent Application No. 2013-130935, filed on Jun. 21, 2013. The foregoing patent applications are herein incorporated by reference by entirety for all purposes.

### FIELD OF THE INVENTION

The present invention relates to a method and apparatus for removing a tantalum oxide film existing on a silicon substrate.

### BACKGROUND OF THE INVENTION

Recently, in accordance with a demand for high integration and high speed of LSI (large-scale integration), a design rule of a semiconductor device constituting LSI is further miniaturized. Along with such trend, a high dielectric constant material (high-k material) capable of forming a thinner film is used as a gate insulating film of a CMOS (complementary metal-oxide semiconductor) device and an insulating film of a capacitor of DRAM (dynamic random access memory).

HfO₂, ZrO₂ and the like are being used as the high-k material, and recently, Ta₂O₅ having a higher permittivity is also considered as the high-k material (see, e.g., Patent document 1).

In a case of using Ta₂O₅ as a gate insulating film or a capacitor insulating film, a predetermined pattern is formed by performing a dry etching after forming a film. However, since a vapor pressure of an etching product is low, a film containing tantalum and oxygen is reattached to an end portion of a silicon substrate. Further, when a Ta₂O₅ film is formed on the silicon substrate, the film forming is performed in a single-substrate type or in a batch-type. However, in a case of a batch-type film forming, the film forming is performed even on a backside of the silicon substrate, so that the Ta₂O₅ film formed on the backside needs to be removed.

If a subsequent process is performed in a state where the film containing tantalum and oxygen reattached to an end portion of the substrate and the Ta₂O₅ film formed on the backside of the substrate (hereinafter, both are called a tantalum oxide film) exist, there occurs a problem such as cross contamination between the processes. Accordingly, it is required to remove the tantalum oxide film attached. As a method of removing the tantalum oxide film without damaging the silicon substrate, there is considered a method that performs a wet cleaning by using, as a chemical solution, hydrofluoric acid (HF) which is used in a removal of a HfO₂ film or a ZrO₂ film. In addition, Patent document 2 discloses a method of removing the tantalum oxide film by using hydrofluoric acid or buffered hydrofluoric acid (BHF).

### Patent Document

Patent Document 1: Japanese Patent Application Publication No. 2012-178553

Patent Document 2: Japanese Patent Application Publication No. 2012-500480

However, it has been proved that the Ta₂O₅ film has an extremely low etching rate with the hydrofluoric acid and is not practical, whereas the HfO₂ film or the ZrO₂ film is easily dissolved in the hydrofluoric acid.

In a field of analytical chemistry, a liquid mixture of hydrofluoric acid and nitric acid and a liquid mixture of hydrofluoric acid, sulfuric acid and nitric acid are being used in a decomposition/dissolution method of a Ta₂O₅ specimen having a low solubility. However, it is required to perform a high temperature processing or a microwave processing together with the method. Accordingly, if considering the application to a semiconductor device, it is difficult to form a hard face. Further, since the liquid mixture of hydrofluoric acid and nitric acid etches silicon and the reactivity is higher than that with Ta₂O₅, it is difficult to apply the liquid mixture to removal of the film on the silicon substrate.

### SUMMARY OF THE INVENTION

In view of the above, the present invention provides a tantalum oxide film removal method and apparatus capable of removing a tantalum oxide film existing on a silicon substrate at a low temperature with a high speed without damaging the silicon substrate.

In accordance with a first aspect of the present invention, there is provided a method of removing a tantalum oxide film, which includes: providing a silicon substrate having the tantalum oxide film; making a mixed aqueous solution including hydrofluoric acid and organic acid contact with the tantalum oxide film; and removing the tantalum oxide film from the silicon substrate by a reaction between the mixed aqueous solution and the tantalum oxide film.

In the first aspect, the tantalum oxide film may be attached to the silicon substrate or may be formed on an entire surface of a backside of the silicon substrate. The organic acid may be selected from a group consisting of acetic acid, formic acid and oxalic acid. Particularly, the acetic acid is preferable.

A concentration of the organic acid in the mixed aqueous solution may be 40 mass % or above. In this case, in the mixed aqueous solution, a concentration of the hydrofluoric acid may be in a range of 1 to 30 mass % and the concentration of the organic acid is in a range of 40 to 98 mass %. A temperature of the mixed aqueous solution may be room temperature to 100° C.

The mixed aqueous solution may be supplied to the silicon substrate while the silicon substrate is rotated.

In accordance with a second aspect of the present invention, there is provided a tantalum oxide film removal apparatus for removing a tantalum oxide film existing on a silicon substrate, the apparatus including: a support mechanism configured to rotatably support the silicon substrate; a rotation mechanism configured to rotate the support mechanism; a liquid supply unit configured to supply a mixed aqueous solution including hydrofluoric acid and organic acid; and a nozzle configured to eject the mixed aqueous solution from the liquid supply unit to the silicon substrate supported on the support mechanism, wherein the mixed aqueous solution ejected from the nozzle contacts with the tantalum oxide film existing on the silicon substrate to remove the tantalum oxide film.

In accordance with a third aspect of the present invention, there is provided a non-transitory computer-readable storage medium storing a program which is operated on a computer to control a tantalum oxide film removal apparatus, wherein the program controls, when executed on the computer, the tantalum oxide film removal apparatus to perform a method of removing a tantalum oxide film, the method including: providing a silicon substrate having the tantalum oxide film; and making a mixed aqueous solution including hydrofluoric acid and organic acid contact with the tantalum oxide film.

In accordance with the present invention, by making the mixed aqueous solution including hydrofluoric acid and organic acid contact with the tantalum oxide film existing on the silicon substrate, the tantalum oxide film can be removed at a low temperature with a high speed without damaging the silicon substrate.

### BRIEF DESCRIPTION OF THE DRAWINGS

FIG. 1 is a cross sectional view showing a tantalum oxide film removal apparatus for performing a method of removing a tantalum oxide film in accordance with an embodiment of the present invention.

FIG. 2 is a view showing a comparison result between an etching rate of when a tantalum oxide film is etched with a mixed aqueous solution of hydrofluoric acid and an organic acid (acetic acid) and etching rates of when the tantalum oxide film is etched with each of hydrofluoric acid plus pure water, hydrofluoric acid plus hydrochloric acid plus pure water, and hydrofluoric acid plus hydrogen peroxide solution.

FIG. 3 is a view showing a relationship between a concentration of acetic acid in the mixed aqueous solution and an etching rate of the tantalum oxide film.

### DETAILED DESCRIPTION OF THE EMBODIMENTS

The present inventors repeatedly carried out various examinations to solve the aforementioned problem. As a result, it has been found that a tantalum oxide film existing on a silicon substrate can be removed at a low temperature with a high speed without damaging the silicon substrate by using a mixed aqueous solution including hydrofluoric acid and organic acid. Conventionally, it was unimaginable to use an organic acid in an etching of a material having a low solubility. However, it has been found for the first time that by mixing the organic acid with hydrofluoric acid and pure water, only the tantalum oxide film can be etched and removed at a low temperature with a high speed without damaging silicon constituting the substrate.

The reason therefor is not certainly clear. However, it may be supposed to have relevance as follows: a fluoro complex compound (HTaF₆, H₂TaF₇ and the like) of tantalum is formed under the existence of the hydrofluoric acid and the organic acid, and the complex compound is easily dissolved by the mixed aqueous solution of hydrofluoric acid and organic acid; the mixed aqueous solution of hydrofluoric acid and organic acid has a high wettability with respect to the silicon substrate whereas the hydrofluoric acid alone has a high water repellency with respect to the silicon substrate; and the like.

The present invention is achieved based on such knowledges.

Hereinafter, embodiments of the present invention will be described in detail with respect to the accompanying drawings.

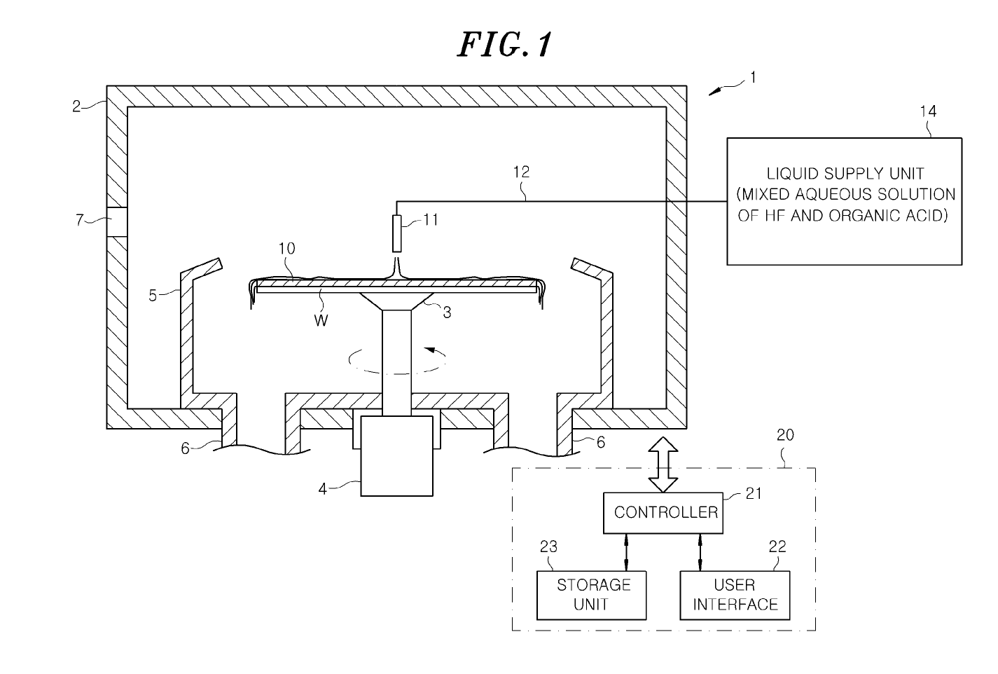

FIG. 1 is a cross-sectional view showing a tantalum oxide film removal apparatus for performing a method of removing a tantalum oxide film in accordance with an embodiment of the present invention.

The tantalum oxide film removal apparatus 1 includes a chamber 2. A substrate W having a Ta₂O₅ film 10 formed on a backside thereof is accommodated in the chamber 2. A silicon substrate (silicon wafer) is used as the substrate W. Alternatively, the substrate W may be one that has a film containing tantalum and oxygen reattached to an end portion of the substrate W.

The tantalum oxide film removal apparatus 1 further includes a spin chuck 3 for horizontally supporting the substrate W by vacuum-suction. The spin chuck 3 can be rotated by a motor 4. A cup 5 is installed in the chamber 2 to cover the substrate W supported on the spin chuck 3. A gas and liquid exhaust line 6 is installed at a bottom portion of the cup 5 to extend under the chamber 2. A loading/unloading port 7 through which the substrate W is loaded and unloaded is provided at a sidewall of the chamber 2. The substrate W is supported on the spin chuck 3 such that the backside on which the Ta₂O₅ film 10 is formed is up.

A nozzle 11 for ejecting a liquid for removing the Ta₂O₅ film 10 formed on the backside of the substrate W is installed above the substrate W supported on the spin chuck 3. The nozzle 11 is movable in horizontal and vertical directions by a driving mechanism (not shown). As shown in FIG. 1, in a case where the Ta₂O₅ film 10 is formed in an entire surface of the backside of the substrate W, the nozzle 11 is arranged at a position corresponding to a center of the substrate W. Further, in a case of removing a film containing tantalum and oxygen reattached to an end portion of the substrate W, the nozzle 11 may be arranged at a position depending on the attachment situation of the film.

A liquid supply line 12 is connected to the nozzle 11. A mixed aqueous solution of hydrofluoric acid (HF) and organic acid is supplied, as a liquid for removing the Ta₂O₅ film 10, through the liquid supply line 12 from a liquid supply unit 14.

The liquid supply unit 14 includes supply sources for respectively supplying hydrofluoric acid, an organic acid and pure water (DIW (deionized water)) and a valve system and a flow rate control system for controlling a mixing ratio thereof.

The tantalum oxide film removal apparatus 1 further includes a control unit 20. The control unit 20 includes a controller 21, a user interface 22 and a storage unit 23. The controller 21 includes a microprocessor (computer) which controls the respective components of the tantalum oxide film removal apparatus 1, e.g., the motor 4, the driving mechanism of the nozzle 11, the valve system and the flow rate control system of the liquid supply unit 14, and the like. The user interface 22 includes a keyboard through which an operator performs an input operation of a command to manage the tantalum oxide film removal apparatus 1, a display on which an operation situation of the tantalum oxide film removal apparatus 1 is visually displayed, and the like. The storage unit 23 stores process recipes including a control program for controlling control targets of the respective components of the tantalum oxide film removal apparatus 1 and a program for allowing the tantalum oxide film removal apparatus 1 to perform a predetermined process. The process recipes are stored in a storage medium of the storage unit 23. The storage medium may be a fixed one such as a hard disk, or a transportable one such as a CDROM (compact disc read-only memory), a DVD (digital versatile disk), a flash memory and the like. Alternatively, the recipes may be properly transmitted from another device through, e.g., a dedicated line. As occasion demands, a recipe is called from the storage unit 23 by an instruction from the user interface 22 and executed in the controller 21, so that a predetermined process is performed under the control of the controller 21.

Next, description will be made on a method of removing the tantalum oxide film existing on the substrate W by using the tantalum oxide film removal apparatus 1.

First, the substrate W having the Ta₂O₅ film 10 formed on the backside thereof is loaded into the chamber 2 and supported on the spin chuck 3 in a state where the backside is up. The substrate W has an undesired Ta₂O₅ film formed on the backside of the substrate W in, e.g., a batch type film formation, and the undesired Ta₂O₅ film 10 needs to be removed. Alternatively, the substrate W may have a film containing tantalum and oxygen reattached to the end portion of the substrate W by, e.g., the etching of the Ta₂O₅ film, and the reattached film may need to be removed. In this case, depending on the attachment situation of the film, the backside of the substrate W may be placed up or the top surface of the substrate W may be placed up.

Thereafter, the nozzle 11 is placed above the substrate W at a position corresponding to a center of the substrate W. While the substrate W is rotated together with the spin chuck 3 by the motor 4, the mixed aqueous solution of hydrofluoric acid and organic acid, which serves as a liquid for removing the Ta₂O₅ film 10, is supplied from the liquid supply unit 14 to the upper surface of the substrate W through the liquid supply line 12 and the nozzle 11.

The mixed aqueous solution supplied to the upper surface of the substrate W spreads toward the outer periphery of the substrate W by centrifugal force and reacts with the Ta₂O₅ film 10. The Ta₂O₅ film 10 is removed from the substrate W by the reaction between the mixed aqueous solution and the Ta₂O₅ film 10.

As such, when the mixed aqueous solution of hydrofluoric acid and organic acid is applied to the Ta₂O₅ film 10, the Ta₂O₅ film 10 solely can be etched and removed at a low temperature with a high speed without damaging a silicon constituting the substrate W. Also in a case of the film containing tantalum and oxygen reattached to the end portion of the substrate W, the film can be removed by the mixed aqueous solution of hydrofluoric acid and organic acid without damaging the silicon, similarly to the Ta₂O₅ film 10.

The reason therefor is not certainly clear. However, it may be supposed to have relevance as follows: a fluoro complex compound (HTaF₆, H₂TaF₇ and the like) of tantalum is formed under the existence of the hydrofluoric acid and the organic acid, and the complex compound is easily dissolved by a mixed aqueous solution of the hydrofluoric acid and the organic acid; the mixed aqueous solution of hydrofluoric acid and organic acid has a high wettability with respect to the silicon substrate whereas the hydrofluoric acid alone has a high water repellency with respect to the silicon substrate; and the like.

As described above, since the mixed aqueous solution of hydrofluoric acid and organic acid has a high wettability with respect to the silicon constituting the substrate W, the process efficiency and process uniformity can be maintained high. This is because, in a case of employing a method in which a chemical solution is supplied while the substrate W is rotated, as the chemical solution has a higher wettability with respect to the substrate, the process efficiency is improved and a more uniform process can be performed. The wettability of the mixed aqueous solution can be controlled by a ratio of the hydrofluoric acid and the organic acid.

Further, as to the hydrofluoric acid in the mixed aqueous solution, the undiluted solution of the hydrofluoric acid is formed of 50% aqueous solution. Therefore, pure water is inevitably included in the mixed aqueous solution.

As to the organic acid in the mixed aqueous solution, carboxylic acid, sulphonic acid, or phenols may be used as the organic acid, but the carboxylic acid is more preferably used. The carboxylic acid may be expressed as a general formula: R—COOH (where R is hydrogen; alkyl radical or akenyl radical of C₁ to C₂₀ in a straight chain or branched chain; or preferably methyl, ether, propyl, butyl, pentyl, or hexyl). The carboxylic acid may be formic acid (HCOOH), oxalic acid ((COOH)₂), acetic acid (CH₃COOH), propionic acid (CH₃CH₂COOH), butyric acid (CH₃(CH₂)₂COOH), valeric acid (CH₃(CH₂)₃COOH), or the like. Among them, formic acid (HCOOH), acetic acid (CH₃COOH) and oxalic acid ((COOH)₂) are preferable, and acetic acid is more preferable. The concentration of the undiluted solution of the organic acid is close to 100%, unlike the hydrofluoric acid. For example, the concentration of the undiluted solution of the acetic acid is 99%.

A temperature of the mixed aqueous solution of hydrofluoric acid and organic acid is preferably set in a range of room temperature to 100° C. The Ta₂O₅ film can be sufficiently removed by the mixed aqueous solution of hydrofluoric acid and organic acid of room temperature to 100° C., e.g., 50° C. It is not required to make the mixed aqueous solution become a high temperature, unlike the cases of using a liquid mixture of hydrofluoric acid and nitric acid and using a liquid mixture of hydrofluoric acid, sulfuric acid and nitric acid.

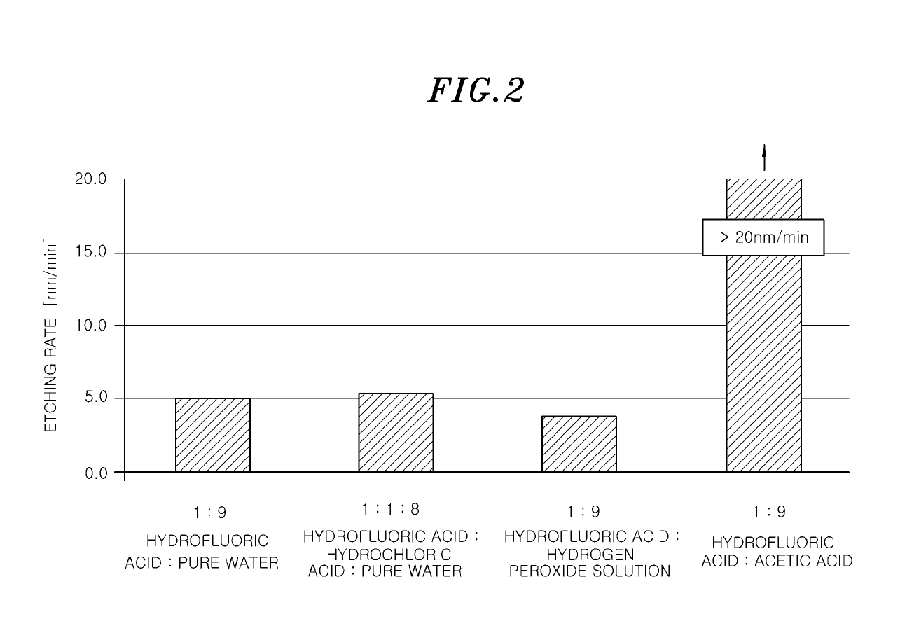

Actually, a test was carried out to confirm that the mixed aqueous solution of hydrofluoric acid and organic acid is effective in removing the Ta₂O₅ film, and the test result is shown as follows. Herein, acetic acid (CH₃COOH) was used as the organic acid. An etching rate of when the Ta₂O₅ film is etched by a mixed aqueous solution of hydrofluoric acid and acetic acid (a ratio of the undiluted solutions of the hydrofluoric acid and the acetic acid is 1:9) was compared with etching rates of when the Ta₂O₅ film is etched by each of hydrofluoric acid plus pure water, hydrofluoric acid plus hydrochloric acid plus pure water, and hydrofluoric acid plus hydrogen peroxide solution. Here, a temperature of the liquid was set to 55° C. The result is shown in FIG. 2. As shown in FIG. 2, when using the mixed aqueous solution of hydrofluoric acid and acetic acid, the etching rate was higher than 20 nm/min. However, in the cases of using other liquids, the etching rates were about 4 to 5 nm/min. Therefore, it has been found that the mixed aqueous solution of hydrofluoric acid and acetic acid is effective in removing the Ta₂O₅ film.

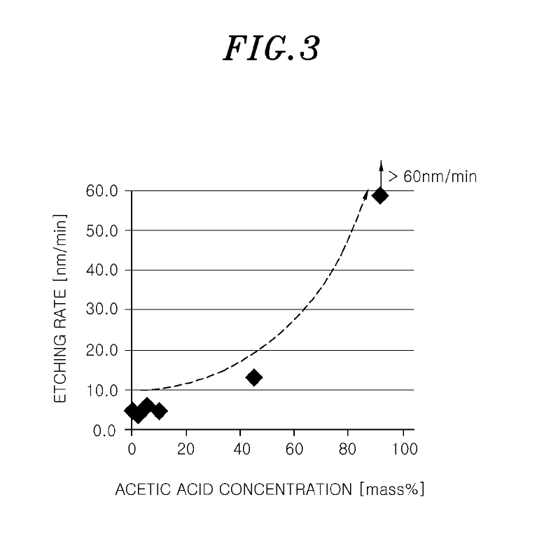

Next, in a case where acetic acid (CH₃COOH) was used as the organic acid and the concentration of the acetic acid in the mixed aqueous solution was changed, the relationship between the acetic acid concentration and the etching rate of the Ta₂O₅ film was examined. The result is shown in FIG. 3. Based on FIG. 3, it has been found that the etching rate is remarkably improved if the acetic acid concentration exceeds 40 mass %. Here, a temperature of the liquid mixture was set to 55° C.

The concentration of the hydrofluoric acid in the mixed aqueous solution is preferably set to 1 to 30 mass % and the concentration of the organic acid in the mixed aqueous solution is preferably set to 40 to 98 mass %. The remainder is pure water. However, since, as described above, the undiluted solution of the hydrofluoric acid is 50% water solution, when the concentration of the hydrofluoric acid is, e.g., the maximum, i.e., 30 mass %, the concentration of the pure water becomes 30 mass % and the concentration of the organic acid becomes almost 40 mass %. If pure water is not additionally added, the concentration of the pure water becomes in a range of about 1 to 30 mass %.

As above, in accordance with the present embodiment, by supplying the mixed aqueous solution including hydrofluoric acid and organic acid to the silicon substrate W having the Ta₂O₅ film 10 formed on the backside thereof, the Ta₂O₅ film 10 is removed from the silicon substrate W. By doing so, the Ta₂O₅ film 10 formed on the backside of the silicon substrate W can be removed at a low temperature with a high speed withough damaging the silicon substrate W. Similarly, also in a case of a film containing tantalum and oxygen reattached to the end portion of the substrate W, the film can be removed at a low temperature with a high speed without damaging the silicon substrate W by supplying the mixed aqueous solution including hydrofluoric acid and organic acid.

While the present invention has been described with respect to the embodiment, it can be variously modified without being limited to the above embodiment. For example, in the above embodiment, there has been shown a case where the substrate is supported on the spin chuck and a liquid mixture is supplied from the nozzle arranged above the substrate. However, the configuration is not limited thereto but the nozzle may be provided at the side of the backside of the substrate or at the outer side of the substrate. That is, an appropriate configuration of the apparatus may be employed depending on an existence situation of the tantalum oxide film.

### DESCRIPTION OF REFERENCE NUMERALS

1: tantalum oxide film removal apparatus

2: chamber

3: spin chuck

4: motor

5: cup

6: gas and liquid exhaust line

7: loading/unloading port

11: nozzle

12: liquid supply line

14: liquid supply unit

20: control unit

21: controller

22: user interface

23: storage unit

W: substrate (silicon substrate)

What is claimed is:

1. A method of removing a tantalum oxide film, comprising:
providing a silicon substrate having the tantalum oxide film;
making a mixed aqueous solution including hydrofluoric acid, organic acid and pure water contact with the tantalum oxide film; and
removing the tantalum oxide film from the silicon substrate by a reaction between the mixed aqueous solution and the tantalum oxide film.

2. The method of claim 1, wherein the tantalum oxide film is attached to the silicon substrate or is formed in an entire surface of a backside of the silicon substrate.

3. The method of claim 1, wherein the organic acid is selected from a group consisting of acetic acid, formic acid and oxalic acid.

4. The method of claim 1, wherein a concentration of the organic acid in the mixed aqueous solution is 40 mass % or above.

5. The method of claim 4, wherein in the mixed aqueous solution, a concentration of the hydrofluoric acid is in a range of 1 to 30 mass % and the concentration of the organic acid is in a range of 40 to 98 mass %.

6. The method of claim 1, wherein a temperature of the mixed aqueous solution is room temperature to 100° C.

7. The method of claim 1, wherein the mixed aqueous solution is supplied to the silicon substrate while the silicon substrate is rotated.

8. A tantalum oxide film removal apparatus for removing a tantalum oxide film existing on a silicon substrate, the apparatus comprising:
a support mechanism configured to rotatably support the silicon substrate;
a rotation mechanism configured to rotate the support mechanism;
a liquid supply unit configured to supply a mixed aqueous solution including hydrofluoric acid, organic acid and pure water; and
a nozzle configured to eject the mixed aqueous solution from the liquid supply unit to the silicon substrate supported on the support mechanism,
wherein the mixed aqueous solution ejected from the nozzle contacts with the tantalum oxide film existing on the silicon substrate to remove the tantalum oxide film.

9. The tantalum oxide film removal apparatus of claim 8, wherein the organic acid is selected from a group consisting of acetic acid, formic acid and oxalic acid.

10. The tantalum oxide film removal apparatus of claim 8, wherein the liquid supply unit supplies the mixed aqueous solution in which a concentration of the organic acid is set to 40 mass % or above.

11. The tantalum oxide film removal apparatus of claim 10, wherein the liquid supply unit supplies the mixed aqueous solution in which a concentration of the hydrofluoric acid is set in a range of 1 to 30 mass % and the concentration of the organic acid is set in a range of 40 to 98 mass %.

12. The tantalum oxide film removal apparatus of claim 8, wherein the liquid supply unit supplies the mixed aqueous solution of room temperature to 100° C.

13. A non-transitory computer-readable storage medium which is operated on a computer and stores a program for controlling a tantalum oxide film removal apparatus,
wherein the program controls, when executed on the computer, the tantalum oxide film removal apparatus to perform a method of removing a tantalum oxide film, the method including: providing a silicon substrate having the tantalum oxide film; and making a mixed aqueous solution including hydrofluoric acid, organic acid and pure water contact with the tantalum oxide film.
